(19) United States
(12) Patent Application Publication
(10) Pub. No.: US 2010/0102997 A1
(43) Pub. Date: Apr. 29, 2010

(54) Device for entering fuel price information into vehicles.

(76) Inventor: John Pierre Pikolon, Hamilton (CA)

Correspondence Address: John Pikolon, 37 Paisley Ave. North, Hamilton, ON, L8S 4G5, CA

(21) Appl. No.: 12/558,669

(22) Filed: Sep. 14, 2009

Related U.S. Application Data
(60) Provisional application No. 61/197,435, filed on Oct. 28, 2008.

(51) Int. Cl. H03M 11/00; B67D 7/08

(52) U.S. Cl. 341/22; 141/98

(57) ABSTRACT

A vehicular number input device used for entering fuel/energy price information into a vehicle's internal computer, mileage computer, mileage software or software monitoring system. This number input device is secured to the vehicle near the gas cap. The fuel/energy price data entered can then be displayed to show real-time fuel efficiency in terms of dollars and cents during the operation of the vehicle or when it has stopped. The optimal device claimed has the best advantage for fuel cost input since it is simple to use and inexpensive to produce.

The location of the device is convenient since a user who is pumping gas/recharging power usually has a few moments to himself to enter numbers while the gas is being filled. It's the perfect opportunity to enter fuel price data into a vehicle's computer. This device provides a simple, unique and convenient option for drivers wishing to view of their vehicle's fuel expense consumption costs as it occurs.

### CROSS-REFERENCE TO RELATED APPLICATIONS

None.

### FEDERALLY SPONSORED RESEARCH

None.

### SEQUENCE LISTING

None.

### BACKGROUND OF THE INVENTION

This invention relates to vehicular recording and input devices. In particular, this invention relates to number inputting of gasoline price information (or kilowatt price information) into a vehicle's internal computer, mileage computer or software monitoring system through a numerical input device that has rotating digits that are located near the gasoline cap; the gasoline cap that is normally screwed onto the fuel tank filler neck of a vehicle. In the case of plug in vehicles, a number input device would be located where a recharge power cord is connected.

Therefore it is an object of this invention to provide a convenient device and a convenient location for entering gasoline/kilowatt price information. This base data can then be used in a number of ways which will become apparent to those skilled in the art of internal vehicle computers, mileage computers or software monitoring systems, display and vehicular manufacturers.

For example, it may be used to display real-time information on how much gasoline (in terms of cost i.e. dollars and cents) is being used at any given moment during vehicular operation. Another example of how fuel/price information could be used would be calculate and show exactly how much a certain trip cost. This would be similar to a tripometer only that instead of total distance being displayed it would show the total cost of a particular trip.

It is still the further object of this invention to provide a convenient device for inputting gas price numerical data that is easy to use and inexpensive to produce. Rotating numerical dials are a convenient input method however others are possible such as a numerical input pad, voice recognition, transponder signals, radio signals or microwave signals for gathering information about the price of gasoline being put into said cars fuel tank.

Rotating numerical dials have an advantage for price input since it is simple, space efficient, reliable, easy and inexpensive to produce. Another advantage to this first input device is that it is quick to use. Since gasoline prices are usually around the same price range (within 20 cents or so) the vehicular user only has to turn a couple of knobs (up or down) to match the price of fuel they are filling their gas tank with. The location is very convenient since a user who is filling their vehicle with fuel usually has a few moments to him/herself to do something while the gas is being filled. It's the perfect opportunity to rotate some numerical switches and input the current fuel price information being purchased. So far, no prior art has claimed such a device in such a location.

It is a still further object of this invention to provide the most useful way of presenting gasoline cost data to a vehicular user. Specifically, presenting the vehicle's gasoline consumption cost in terms of TIME (per second, per minute, per hour, per day, per week, per month, per year) and LENGTH (per mile, per kilometer, miles per gallon, miles per charge, per 100 kilometers, per trip). The user of a vehicle may view the fuel consumption cost HISTORY (previous day, previous week, previous month, previous year, previous trip). DISPLAY preferences about the amount of time information is shown on the dashboard can be set as desired (5 seconds, 20 seconds, 1 minute, entire trip, always). Default settings can be reset and the memory of the system can be cleared.

It is still the further the object of this invention to provide the vehicle user the option of entering gasoline/kilowatt price data or choosing NOT to. If the user wishes NOT to enter fuel/energy price data, they may leave the input data at $ 000.00 (ZERO) and no fuel cost data will be entered or processed by the vehicle's internal computer, mileage computer or software monitoring system.

It is still the further object of this invention to allow the data to be used in an accurate way. Since vehicle users rarely fill their tank of gas on an empty tank, a certain amount of mixing of previous gasoline fills will occur. The vehicle's onboard computer, mileage computer or software monitoring system will take into the account the previous volume and fuel price data and combine it with the new fuel price data and volume of fuel being pumped into the fuel tank. The cost/volume of any previous amount gasoline will be averaged with the cost/volume of any new amount of fuel/energy. This will help the mileage system to display more accurate information about the vehicle's actual gasoline consumption cost.

The programming specifics of calculating the cost average would be apparent to those skilled in the art of onboard vehicle computers, mileage computers, mileage software, software monitoring systems, vehicular engineering and production.

These and other objects and features of the present invention will become apparent to those skilled in the art from a consideration of the following summary, drawings, detailed description and claims.

### BRIEF SUMMARY OF THE INVENTION

In accordance with the present invention there is provided a device for the input and storage of vehicular data for the use in a vehicle comprising:

(a) a first input means securable to the vehicle for inputting numerical fuel/energy price information into said vehicle;

(b) a second input means operable by an occupant of the vehicle;

(c) a data storage and internal processing means attached to the first and second input means containing random access memory capability for receiving information from the first and second input means; and

(d) a display system showing the cost of fuel usage in various ways such as TIME or DISTANCE.

Alternative embodiments are possible such as using a numerical keypad, voice recognition technology, transponder technology, radio technology, microwave technology or electromagnetic technology may be used as a first input means.

### BRIEF DESCRIPTION OF THE SEVERAL VIEWS OF THE DRAWINGS

This invention will now be described in one embodiment with reference to the accompanying drawings in which:

FIG. 1 is a schematic drawing of the first input device specifically showing the numerical input device with rotating numerical switches secured above the gasoline cap that is screwed onto the fuel tank filler neck;

FIG. 2 is a schematic drawing of the second input device specifically showing the buttons used for the menu driven logic tree.

FIG. 3 are functional block diagrams of the a logic tree used in the operation of this device;

FIG. 4 is a situational drawing showing how someone may use the device at a gas station. It shows the user adjusting the numbered device knobs to match the price of gasoline.

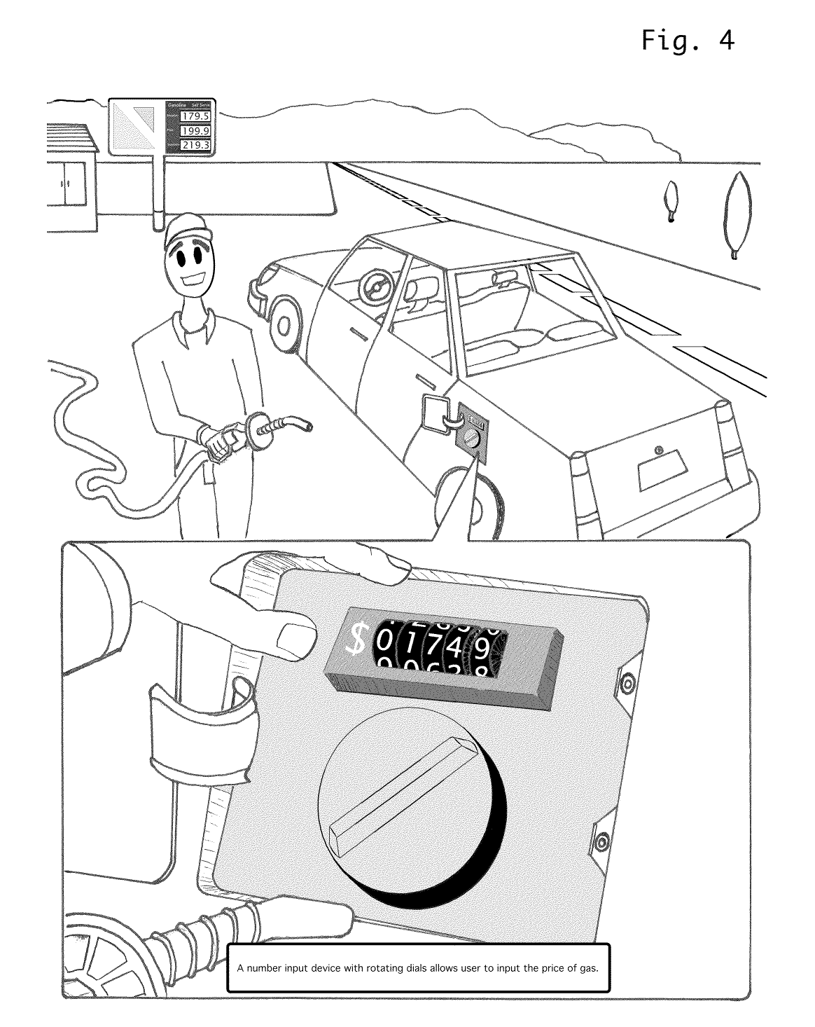

FIG. 5 is a continuation of FIG. 4. The display area on the dashboard shows the user the current rate of driving at 8 cents per kilometer. It also shows that the total cost of the trip so far is $ 8.52.

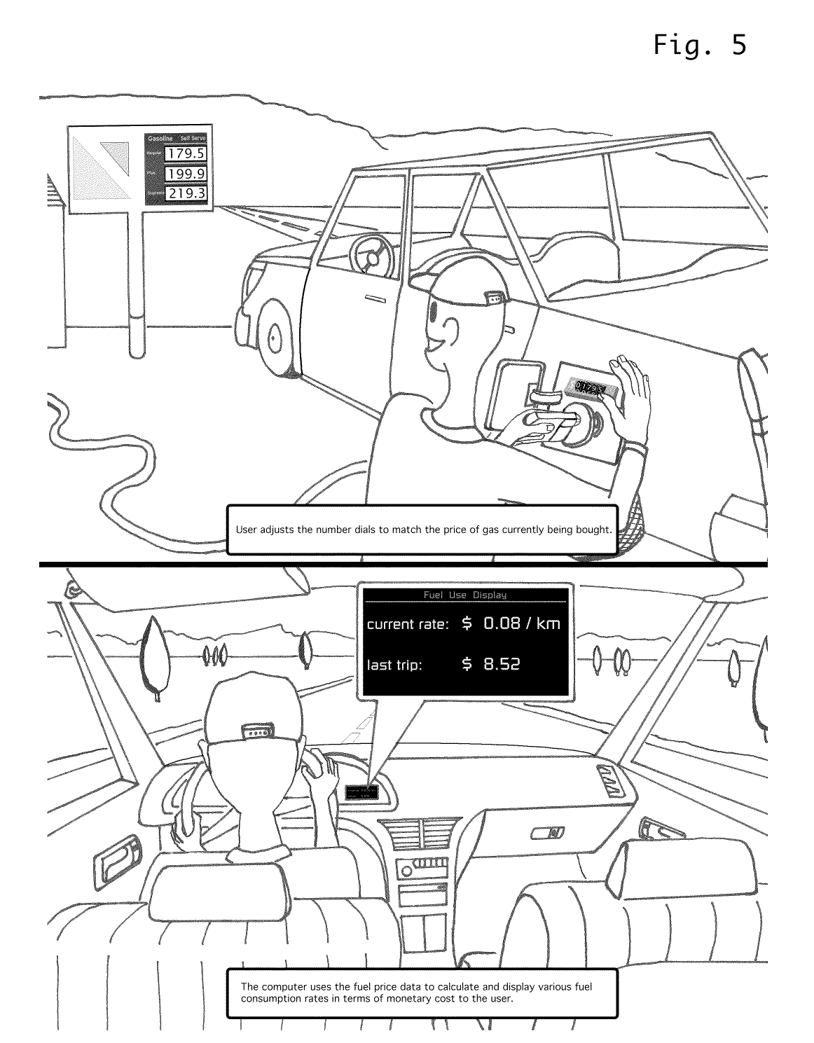

REFERENCE NUMERALS

| | |
|---|---|
| 10 first input device | rolling numbers switch |
| 11 gasoline cap | |
| 12 second input device | for display menu |
| 13 mode/on button | |
| 14 UP button | |
| 15 DOWN button | |
| 16 enter/OFF button | |
| 17 TIME | MENU option |
| 18 per minute | submenu |
| 19 per hour | submenu |
| 20 per day | submenu |
| 21 per week | submenu |
| 22 per month | submenu |
| 23 per year | sub menu |
| 24 LENGTH | MENU option |
| 25 per mile/KM | submenu |
| 26 MPG/per 100 km | submenu |
| 27 per trip | submenu |
| 28 HISTORY | MENU option |
| 29 previous day | submenu |
| 30 previous week | submenu |
| 31 previous month | submenu |
| 32 previous year | submenu |
| 33 previous trip | submenu |
| 34 DISPLAY | MENU option |
| 35 5 seconds | submenu |
| 36 20 seconds | submenu |
| 37 1 minute | submenu |
| 38 entire trip | submenu |
| 39 OFF | MENU option |
| 40 reset defaults | submenu |
| 41 memory clear | submenu |

### DETAILED DESCRIPTION OF THE INVENTION

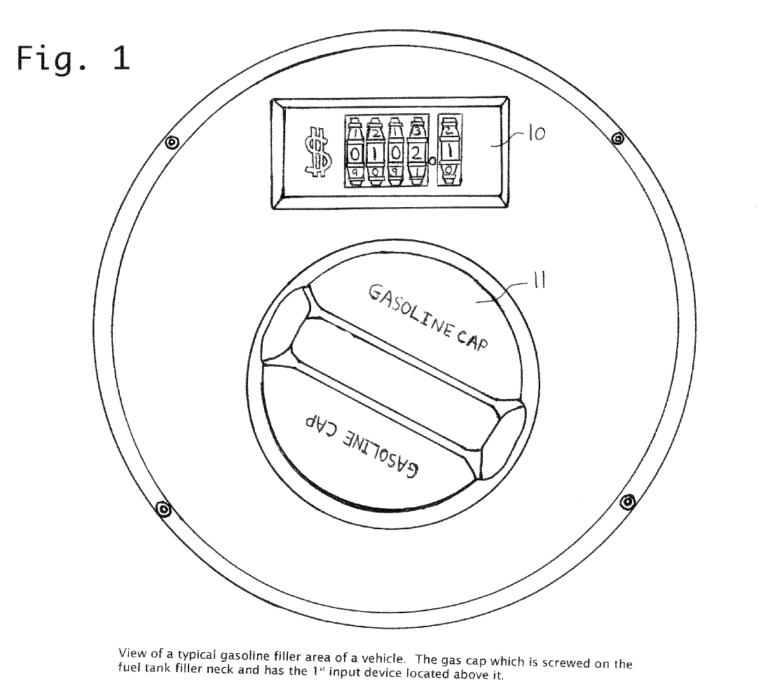

(See FIG. 1)

Although the invention is adaptable to a wide variety of uses it is shown for the purpose of illustration as a device for entering gasoline price (10) embodied in a first input means securable to a vehicle above the gasoline (11) cap which is normally found screwed onto the fuel tank filler neck for inputting gasoline price information into said vehicle; a data storage and internal processing means that is connected the first input means which includes a random access memory means for storing and internally processing data; a second input means operable by an occupant of the vehicle for selecting how to display said vehicle's consumption of gasoline in terms of cost.

Although the invention can be arranged and modified in different ways it is shown for the purpose of illustration as a first input device (10) located and built above where the gas cap is normally screwed on into position on the fuel tank filler neck (11). The first input device allows any user of the vehicle to enter the price of gasoline after a fill or partial fill of gasoline into the vehicle. Although many different locations of the device can be conceived, for the ease of use the device is designed to be placed above the opening of a fuel tank filler neck visible to the user when the gas cap is on the fuel tank filler neck or off the fuel tank filler neck.

For safety reasons, any input device located near the gas cap must be designed to be water proof (for cleaning) AND spark-proof so that there is NO chance and fuel being ignited. This can be achieved by using sealed parts OR covering the dials/buttons with a lid OR creating only mechanical parts on the exterior and connecting any electronic components well inside the vehicle to those mechanical parts OR a combination of all of these items OR such safety designs and precautions that are apparent to those skilled in the art.

Although many different methods of inputting numerical data can be conceived, for ease of use the device (10) is designed to have 5 rolling switches of 0-9 digits allowing the user to input numerical values of 0000.0 to 9999.9

As an example $0129.1 is shown in FIG. 1 and represents $1.29.1 or ‘one dollar and twenty-nine point one cents’. Numerical rolling switches such as combination locks or other rotating dials are conventionally available and known to those skilled in the art.

To enter a gas price, the user of the vehicle would rotate the numerical knobs until the matching gas price or any gas price of the user's choosing would appear on the 1^{st} input device. Entering the gas price can happen at any time either before pumping gas into the vehicle, during or after the gas has been pumped into the car. The vehicles said mileage system, well known to those skilled in the art and are conventionally available, would keep track of all gasoline data inputted and combine the cost of previous gas (whatever is leftover) with the amount of new gas in the car and provide an accurate cost level of consumption by the vehicle at anytime.

If the gasoline price switch is left at 000.00, the vehicle's internal computer, mileage computer, mileage software or software monitoring system will make no gasoline cost calculations.

Gasoline price information is transferred to the vehicle's internal computer, mileage computer, mileage software or software monitoring system. Devices for detecting the distance traveled by a vehicle for interpreting the data from an odometer cable or otherwise are conventionally available and are well know to those skilled in the art.

Other embodiments of the invention might include numerical input devices for electric vehicles or hybrid electric vehicles. For hybrid vehicles, the system would be the same, the user would enter the price of gasoline as they fill their fuel tank. With plug-in hybrids or electric vehicles an added feature would be to enter the price of electricity that the user is paying whether charging the vehicle from home or from a paid booth. In both cases, gas mileage or electricity mileage would be calculated for the user of the vehicle and displayed somewhere inside the vehicle.

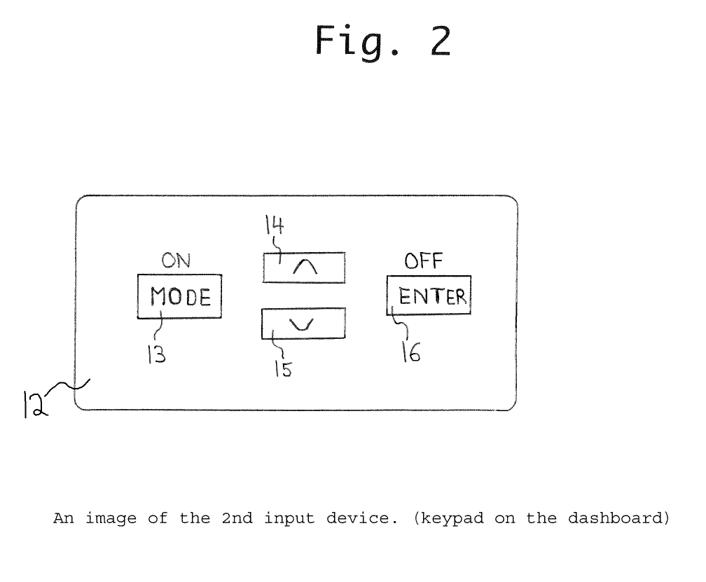

(See FIG. 2)

Although many different methods can be conceived, for ease of use the second input device (12) is located in the vehicle near the drivers dash or odometer system. One embodiment of the button layout of the second input system would have a mode/on switch (13) next to an up (14) and down switch (15) next to a enter/off switch (16). Many alternative button arrangements are possible and apparent to those skilled in the art.

The second input means allows the user to select how their gasoline expense data will be displayed. The data displayed could appear on any existing digital display screens in the vehicle or on a separate display screen devoted to gas expenses only. The data is shown on display by use of any conventional display technique, such as a LCD display or LED display.

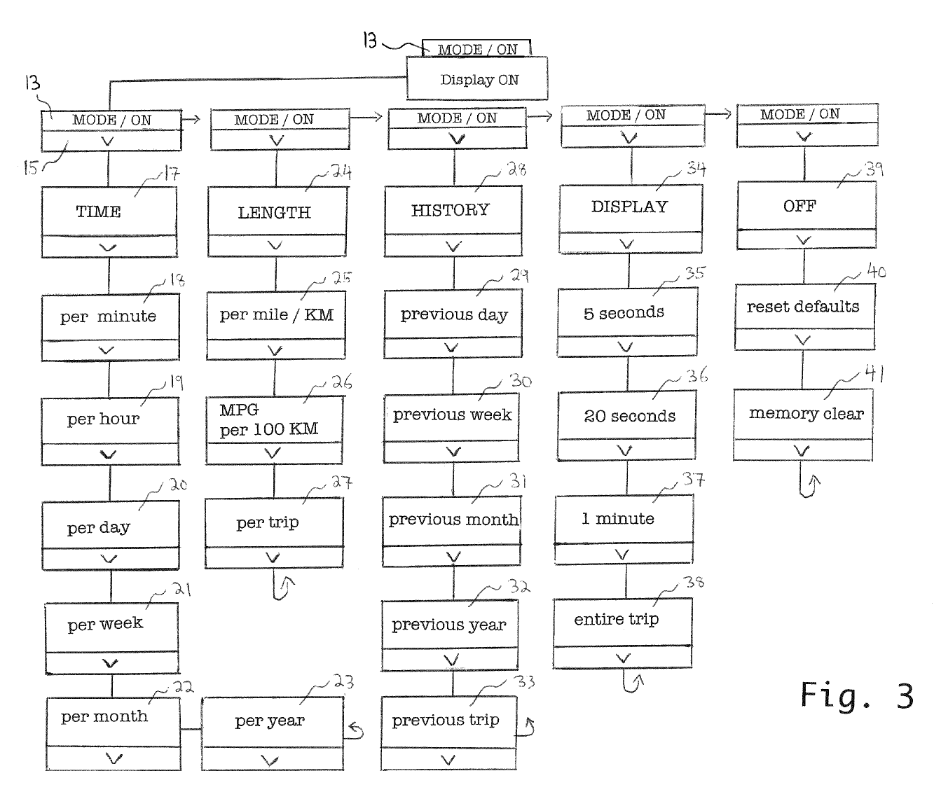

Many different methods of operation of the device can be conceived to those skilled in the art. For the purpose of illustration, one embodiment of the 2nd input device, such as a memory driven logic sequence, is shown in FIG. 3

(See FIG. 3)

If a user of a vehicle wanted to see their gasoline consumption they would press the MODE key (13) to turn the gas cost display on. If no other key is pressed, the display would show the previously selected display choice or a default selection if the system was reset or in first time use.

Pressing the MODE key several times will cycle through a list of menu choices: TIME (17), LENGTH (24), HISTORY (28), DISPLAY (34), OFF (39). Pressing the OFF key (39) during menu selecting will turn off the gas cost display immediately.

Pressing the UP (14) or DOWN (15) arrows will explore the submenus of any menu. Once in a menu, the OFF key (39) will function as an ENTER key to select any submenu.

In the TIME submenu (17), pressing the UP (14) or DOWN (15) keys will cycle through options of PER MINUTE (18), PER HOUR (19), PER DAY (20), PER WEEK (21), PER MONTH (22), PER YEAR (23). Pressing the ENTER/OFF key will select and activate a selected submenu.

In the LENGTH (24) submenu, pressing the UP (14) or DOWN (15) keys will cycle through options of PER MILE/KILOMETER (25), PER GALLON/100 KILOMETER (26), PER TRIP (27). Pressing the ENTER/OFF key will display a selected submenu.

In the HISTORY (28) submenu, pressing the UP (14) or DOWN (15) keys will cycle through options of PREVIOUS DAY (29), PREVIOUS WEEK (30), PREVIOUS MONTH (31), PREVIOUS YEAR (32), PREVIOUS TRIP (33). Pressing the ENTER/OFF key will display a selected submenu.

In the DISPLAY (34) submenu, pressing the UP (14) or DOWN (15) keys will cycle through options of 5 SECONDS (35), 20 SECONDS (36), 1 MINUTE (37), ENTIRE TRIP (38). Pressing the ENTER/OFF key will activate a selected submenu.

In the OFF (39) menu, pressing UP (14) or DOWN (15) keys will cycle through options of OFF (39), RESET DEFAULTS (40) and MEMORY CLEAR (41). Pressing ENTER/OFF on the RESET DEFAULTS submenu will restore all factory default user preferences. ENTER/OFF on the MEMORY CLEAR submenu will clear all mileage memory. Pressing ENTER/OFF on the OFF submenu will turn the display off. When the display is off, trip information and fuel usage calculations are still being made. When the user has set the first input means to zero, no mileage calculations are made at anytime.

1. A device for entering fuel/energy prices into the vehicle's internal computer, mileage computer or software monitoring system by securing a number input device near the gas cap OR power input/recharge plug of a vehicle (this includes all cars, watercraft or aircraft):
specifically, locating/positioning said device either near the opening of the fuel tank filler neck where the gas cap is normally screwed onto or in the cabin of the vehicle or anywhere on the vehicle.
specifically, locating/positioning said device either near the power inlet, recharge plug, power cord, plug-in cord area, or any power input area of a electric vehicle or hybrid electric vehicle or anywhere on the vehicle.
the said numerical device which is convenient for this purpose.
any TYPE of numerical input device located near the opening of the fuel tank filler neck or power inlet/recharge area or inside the cabin of the vehicle or anywhere on the vehicle.
any device receiving fuel price information or electricity price information using a method other than manual input such as radio waves, microwaves, electromagnetism, global positioning system or transponder technology interacting with a vehicle's internal computer, mileage computer or software monitoring system.

2. The numerical device as recited in claim 1, has rolling digits on the mechanism representing the cost of fuel:
the said numerical device as recited in claim 1, may have unlimited amounts of digits or symbols attached to the device.
the said numerical device as recited in claim 1 will be connected to the vehicle's internal computer, mileage computer or software monitoring system.
the said numerical device as recited in claim 1 will provide the base data that will be viewed by the user display by use of any conventional display technique that well known to those skilled in the art.

3. A display system where data inputted from the first input device as recited in claim 1 is displayed to the vehicle's user by use of any conventional input and display technique that is well known to those skilled in the art:
displayed data is controlled by a menu driven keypad consisting of a menu/mode button, an up button, a down button and a enter/exit button.
displayed data is shown per second, per minute, per hour, per day, per week, per month, per year, per mile, per kilometer, miles per gallon, per 100 kilometers, per any length of trip specified by the user.
although different systems of measure may be conceived, for ease of use and manufacture the metric system or imperial system will be used for the calculation and display of lengths
